(19) United States
(12) Patent Application Publication
(10) Pub. No.: US 2025/0280525 A1
(43) Pub. Date: Sep. 4, 2025

(54) MEMORY DEVICE AND FABRICATING METHOD THEREOF

(71) Applicant: NANYA TECHNOLOGY CORPORATION, New Taipei city (TW)

(72) Inventor: Hsu CHIANG, New Taipei City (TW)

(21) Appl. No.: 18/593,904

(22) Filed: Mar. 2, 2024

(51) Int. Cl. H10B 12/00

(52) U.S. Cl. CPC H10B 12/315; H10B 12/03; H10B 12/482

(57) ABSTRACT

A memory device includes a capacitor contact structure, a capacitor, a bit line structure, and a spacer structure. The capacitor contact structure is disposed on a semiconductor substrate. The capacitor is disposed on the capacitor contact structure. The capacitor extends from a top surface of the capacitor contact structure to a sidewall of the capacitor contact structure. The bit line structure is disposed on the semiconductor substrate and adjacent to the capacitor contact structure. The spacer structure is between the bit line structure and the capacitor contact structure.

### BACKGROUND

### Field of Invention

The present disclosure relates to a memory device and a fabricating method thereof.

### Description of Related Art

Memory cells in the dynamic random access memory (DRAM) have been scaled down continuously to integrate a larger number of the memory cells in a unit area. However, some issues of fabricating the memory cells may arise from the scaling down process. For example, a landing pad is typically formed to connect a capacitor and a capacitor contact structure in the DRAM. However, the landing pad increases the resistance of the capacitor contact structure and deteriorates speed performance of the DRAM.

Accordingly, how to provide a memory device and a fabricating method thereof to solve the aforementioned problems becomes an important issue to be solved by those in the industry.

### SUMMARY

An aspect of the disclosure is to provide a memory device and a fabricating method thereof that may efficiently solve the aforementioned problems.

According to an embodiment of the disclosure, a memory device includes a capacitor contact structure, a capacitor, a bit line structure, and a spacer structure. The capacitor contact structure is disposed on a semiconductor substrate. The capacitor is disposed on the capacitor contact structure. The capacitor extends from a top surface of the capacitor contact structure to a sidewall of the capacitor contact structure. The bit line structure is disposed on the semiconductor substrate and adjacent to the capacitor contact structure. The spacer structure is between the bit line structure and the capacitor contact structure.

In some embodiments of the present disclosure, the spacer structure includes a first spacer along a sidewall of the bit line structure and a second spacer along a sidewall of the capacitor contact structure.

In some embodiments of the present disclosure, the first spacer and the second spacer are made of different materials.

In some embodiments of the present disclosure, the first spacer further extends to the sidewall of the capacitor contact structure.

In some embodiments of the present disclosure, the first spacer is in contact with a top surface of the second spacer.

In some embodiments of the present disclosure, the capacitor contact structure includes a lower contact plug and an upper contact plug over the lower contact plug. The top surface of the second spacer is lower than a top surface of the lower contact plug.

In some embodiments of the present disclosure, the spacer structure extends to a top surface of the capacitor contact structure.

In some embodiments of the present disclosure, a bottom surface of the capacitor is in contact with the spacer structure.

In some embodiments of the present disclosure, the bit line structure further includes a bit line and a cap layer over the bit line. The capacitor is in contact with the cap layer.

In some embodiments of the present disclosure, a bottom surface of the capacitor is lower than a top surface of the cap layer.

In some embodiments of the present disclosure, the bit line structure further includes a bit line and a cap layer over the bit line. The spacer structure is in contact with a top surface of the cap layer.

According to another embodiment of the disclosure, a fabricating method of a memory device includes forming a bit line structure over a semiconductor substrate. The fabricating method further includes forming a first spacer along the bit line structure. The fabricating method further includes forming a second spacer along the first spacer. The fabricating method further includes forming a capacitor contact structure along the second spacer. The fabricating method further includes etching back the second spacer to form a gap between the first spacer and the capacitor contact structure. The fabricating method further includes forming a third spacer filling the gap and over the first spacer. The fabricating method further includes etching the first spacer and the third spacer to expose the capacitor contact structure. The fabricating method further includes forming a capacitor electrically connected with the capacitor contact structure.

In some embodiments of the present disclosure, etching the first spacer and the third spacer is performed to expose a top surface and a sidewall of the capacitor contact structure.

In some embodiments of the present disclosure, the capacitor is in contact with the top surface and the sidewall of the capacitor contact structure.

In some embodiments of the present disclosure, etching the first spacer and the third spacer is performed to expose a cap layer of the bit line structure. The capacitor is in contact with the bit line structure.

In some embodiments of the present disclosure, the capacitor contact structure includes a lower contact plug and an upper contact plug over the lower contact plug. Etching back the second spacer is performed such that a top surface of the etched second spacer is lower than a top surface of the lower contact plug.

In some embodiments of the present disclosure, the first spacer and the third spacer include a same material.

In some embodiments of the present disclosure, the third spacer further extends to a top surface of the bit line structure.

In some embodiments of the present disclosure, the third spacer is in contact with a sidewall of the capacitor.

In some embodiments of the present disclosure, the third spacer is in contact with a top surface of the second spacer.

Accordingly, in the memory device of some embodiments of the present disclosure, through the direct and multi-planar connection between the capacitor contact structure and the capacitor, the resistance of the capacitor contact structure may be reduced and the speed performance of the memory device may be improved. In addition, in the fabricating method of the memory device of some embodiments of the present disclosure, the process of forming a landing pad is omitted and the cost of the fabrication may be reduced.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a circuit diagram of a memory device according to some embodiments of the present disclosure;

FIG. 2 is a top view of a memory device according to some embodiments of the present disclosure;

FIG. 3 is a cross-sectional view of a memory device taken along a line 3-3 in FIG. 2 according to some embodiments of the present disclosure; and

FIG. 4 to FIG. 10 are cross-sectional views of intermediate stages of a fabricating method of a memory device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

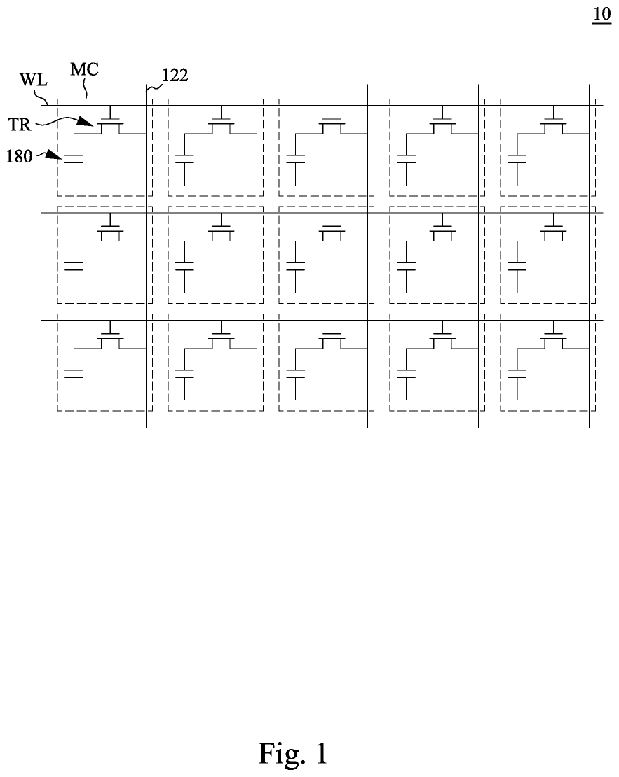

Reference is made to FIG. 1. FIG. 1 is a circuit diagram of a memory device 10 according to some embodiments of the present disclosure. As shown in FIG. 1, the memory device 10 (e.g., dynamic random access memory, DRAM) may include a plurality of memory cells MC. A typical DRAM memory cell incorporates a capacitor 180 and a transistor TR. The capacitor 180 temporarily store data based on the charged state of the capacitor 180. A bit line 122 is electrically connected to a source region of the transistor TR. A word line WL is electrically connected to a gate region of the transistor TR. The capacitor 180 is electrically connected to the corresponding transistor by a capacitor contact structure (not shown in FIG. 1).

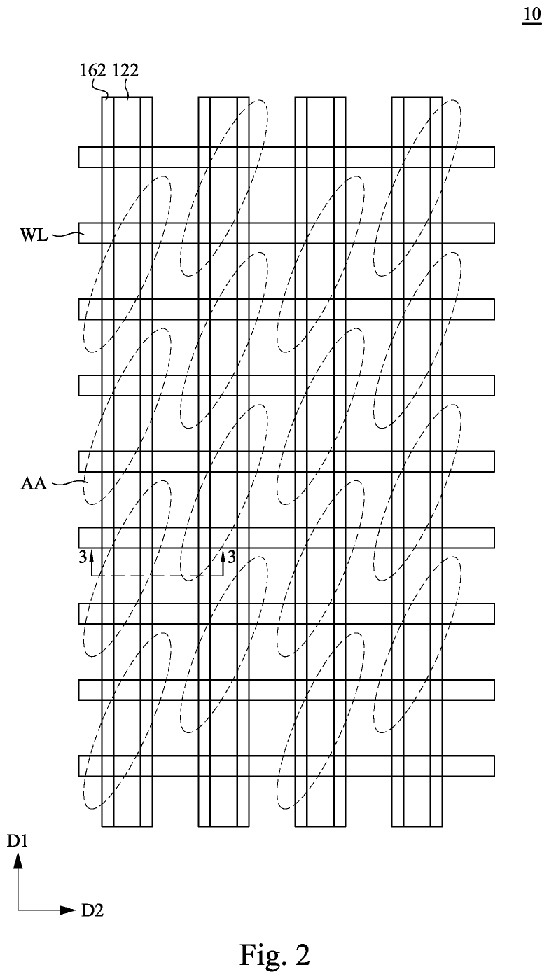

Reference is made to FIG. 2. FIG. 2 is a top view of the memory device 10 according to some embodiments of the present disclosure. It should be noted that FIG. 2 only illustrates some of the components of the memory device 10, and other components such as the capacitor 180 is omitted for simplicity. As shown in FIG. 2, active areas AA, bit lines 122, and word lines WL are formed. To be more specific, the bit lines 122 extend along a first direction D1 and the word lines WL extends along a second direction D2 perpendicular to the first direction D1.

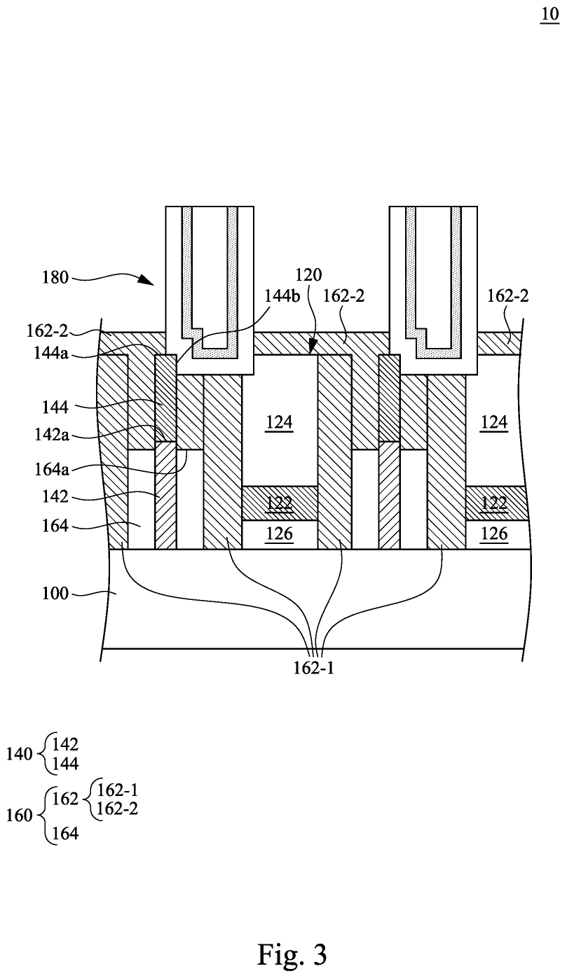

Reference is made to FIG. 3. FIG. 3 is a cross-sectional view of the memory device 10 taken along a line 3-3 in FIG. 2 according to some embodiments of the present disclosure. As shown in FIG. 3, the memory device 10 includes a semiconductor substrate 100, a bit line structure 120, a capacitor contact structure 140, a spacer structure 160, and a capacitor 180.

In some embodiments, the word lines WL are embedded in the active area AA of a substrate. A gate dielectric layer (not shown) may line the surface of each word line WL. Source/drain regions are in the active area AA and on opposite sides of each word line WL. The source/drain regions may include opposite conductivity type than the active area AA. Accordingly, the word line WL, the gate dielectric layer, the source/drain regions, and the active area AA may collectively serve as the transistor TR of the memory cell MC, in which the word line WL and the gate dielectric layer may serve as a gate structure of the transistor TR.

As shown in FIG. 3, the bit line structure 120 and the capacitor contact structure 140 are disposed on the semiconductor substrate 100. The bit line structure 120 is adjacent to the capacitor contact structure 140. The spacer structure 160 is disposed between the bit line structure 120 and the capacitor contact structure 140. The capacitor 180 is disposed on the capacitor contact structure 140. The capacitor 180 is electrically connected to its corresponding transistor through the capacitor contact structure 140. In the present disclosure, the capacitor 180 extends from a top surface of the capacitor contact structure 140 to a sidewall of the capacitor contact structure 140. As such, the connection between the capacitor contact structure 140 and the capacitor 180 is direct and multi-planar. Thus, a typical landing pad may be omitted, and the contact resistance between the capacitor contact structure 140 and the capacitor 180 is thereby reduced.

To be more specific, as shown in FIG. 3, the bit line structure 120 includes a bit line 122, a cap layer 124, and a bit line contact 126. The bit line 122 is disposed on the semiconductor substrate 100 through the bit line contact 126. The cap layer 124 is disposed over the bit line 122. In some embodiments, the bit line 122 includes conductive materials, such as tungsten. The cap layer 124 includes dielectric materials, such as silicon nitride (SIN). The bit line contact 126 may include conductive materials, such as polysilicon.

As shown in FIG. 3, the capacitor contact structure 140 includes a lower contact plug 142 and an upper contact plug 144 over the lower contact plug 142. In some embodiments, the lower contact plug 142 includes poly-crystalline silicon (polysilicon), and the upper contact plug 144 includes conductive materials, such as tungsten.

As shown in FIG. 3, the spacer structure 160 includes a first spacer 162 along a sidewall of the bit line structure 120. To be more specific, the first spacer 162 is disposed along sidewalls of the bit line 122, the cap layer 124, and the bit line contact 126. In some embodiments, the first spacer 162 further extends over and contacts a top surface of the cap layer 124. In some embodiments, the first spacer 162 may include a spacer material 162-1 and a spacer material 162-2.

The spacer structure 160 further includes a second spacer 164 along a sidewall of the capacitor contact structure 140, as shown in FIG. 3. To be more specific, the second spacer 164 is disposed along a sidewall of the lower contact plug 142, surrounding and in contact with the lower contact plug 142.

In some embodiments, the first spacer 162 extends to a sidewall of the capacitor contact structure 140. In greater detail, the first spacer 162 extends to sidewalls of the lower contact plug 142 and the upper contact plug 144. The first spacer 162 then extends and covers a top surface 164a of the second spacer 164.

In some embodiments, the first spacer 162 further extends over and contacts the top surface of the capacitor contact structure 140 (e.g., a top surface 144a of the upper contact plug 144).

The spacer structure 160 includes dielectric materials. In some embodiments, the first spacer 162 and the second spacer 164 are made of different materials. For example, the first spacer 162 includes silicon nitride, and the second spacer 164 includes silicon oxide.

As shown in FIG. 3, the capacitor 180 extends from the top surface 144a to a sidewall 144b of the upper contact plug 144. As such, the connection between the capacitor contact structure 140 and the capacitor 180 is direct at the top surface 144a and the sidewall 144b.

In some embodiments, a bottom surface of the capacitor 180 is in direct contact with the first spacer 162 of the spacer structure 160. In addition, a sidewall of the capacitor 180 may also be in contact with the first spacer 162. In some embodiments, the capacitor 180 may also be in contact with the cap layer 124 of the bit line structure 120. To be more specific, the bottom surface and the sidewall of the capacitor 180 may also be in contact with the cap layer 124.

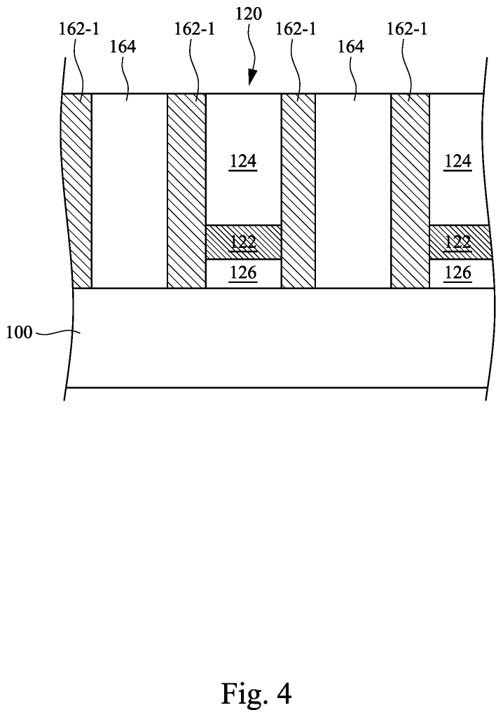

Reference is made to FIG. 4 to FIG. 10. FIG. 4 to FIG. 10 are cross-sectional views of intermediate stages of a fabricating method of the memory device 10 according to some embodiments of the present disclosure. Operations of the fabricating method will be described accompanied with the drawings.

Reference is made to FIG. 4. The fabricating method starts with forming a bit line structure 120 on a semiconductor substrate 100. The semiconductor substrate 100 may include structures such as word lines as aforementioned.

Next, the fabricating method includes forming a spacer material 162-1 along the bit line structure 120 and then forming a spacer material 164 along the spacer material 162-1. In some embodiments, the spacer material 162-1 surrounds the bit line structure 120 and contacts sidewalls of a bit line 122, a cap layer 124, and a bit line contact 126 of the bit line structure 120.

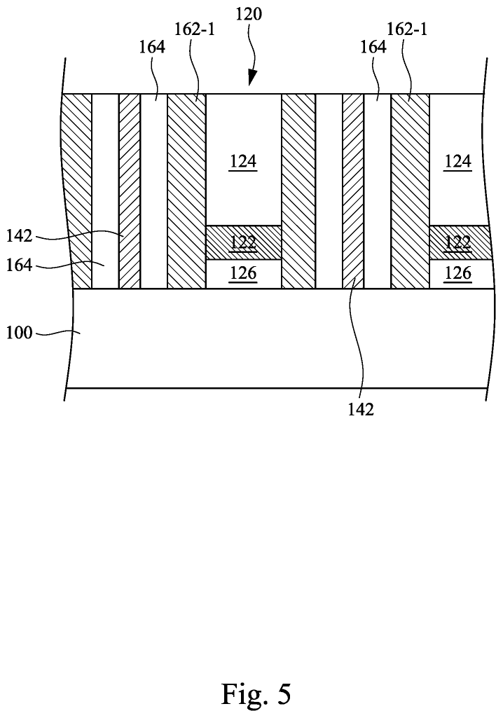

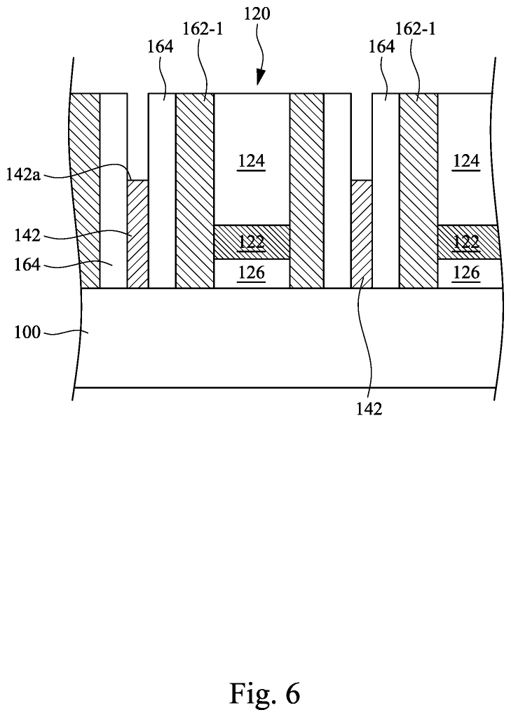

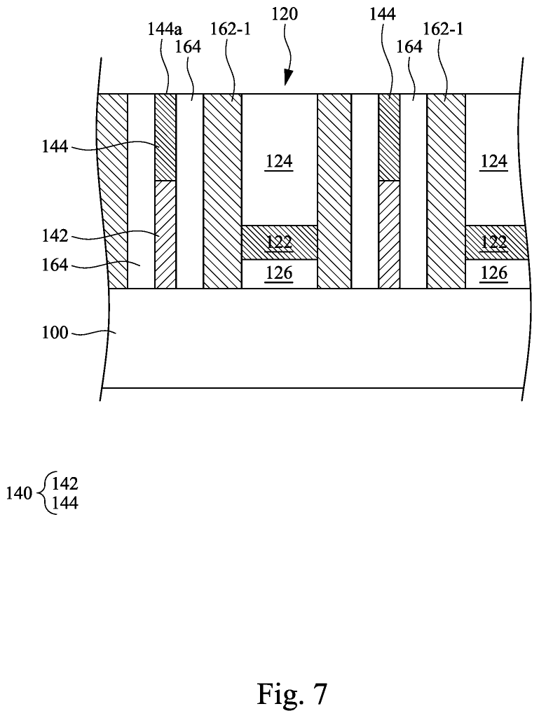

Reference is made to FIG. 5 to FIG. 7. Subsequently, the fabricating method includes forming a capacitor contact structure 140 along the spacer material 164. To be more specific, the capacitor contact structure 140 includes a lower contact plug 142 and an upper contact plug 144 over the lower contact plug 142. As shown in FIG. 5, the lower contact plug 142 is firstly disposed along the second spacer 164. Then, as shown in FIG. 6, the lower contact plug 142 is etched back such that a top surface 142a of the lower contact plug 142 is lower than a top surface of the spacer material 164. Next, the upper contact plug 144 is formed over the etched lower contact plug 142 and a top surface 144a of the upper contact plug 144 is substantially level with the top surface of the spacer material 164, as shown in FIG. 7.

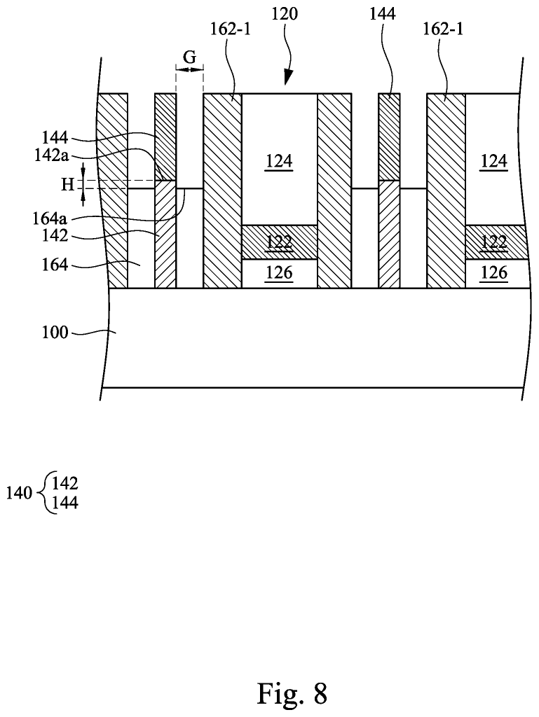

Reference is made to FIG. 8. The fabricating method includes etching back the spacer material 164 to form a gap G between the spacer material 162-1 and the capacitor contact structure 140, as shown in FIG. 8. In some embodiments, etching back the spacer material 164 is performed such that a top surface 164a of the etched spacer material 164 is lower than the top surface 142a of the lower contact plug 142 by a height H. In other words, after the etching process, the upper contact plug 144 and a portion of the lower contact plug 142 protrude from the top surface 164a of the etched spacer material 164. The etched spacer material 164 is also referred to as the second spacer 164.

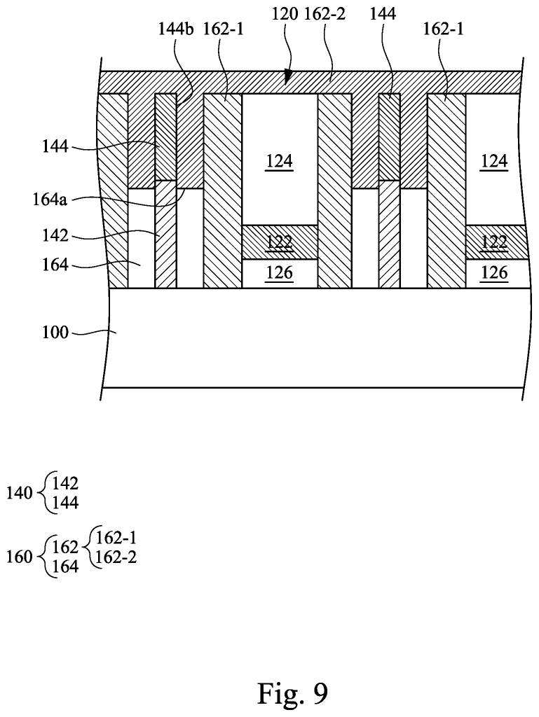

Reference is made to FIG. 9. The fabricating method includes forming a spacer material 162-2 filling the gap G and over the spacer material 162-1, as shown in FIG. 9. In some embodiments, the spacer material 162-2 further extends to a top surface of the bit line structure 120 (e.g., a top surface of the cap layer 124). In some embodiments, the spacer material 162-2 is in contact with the top surface 164a of the second spacer 164. In some embodiments, the spacer material 162-2 is in contact with a sidewall of the capacitor contact structure 140 (e.g., the sidewall 144b of the upper contact plug 144). In some embodiments, the spacer material 162-1 and the spacer material 162-2 include a same material, such as silicon nitride. In other embodiments, the spacer material 162-1 and the spacer material 162-2 include different dielectric materials. The spacer material 162-1 and the spacer material 162-2 are collectively referred to as the first spacer 162. The first spacer 162 and the second spacer 164 are collectively referred to as the spacer structure 160.

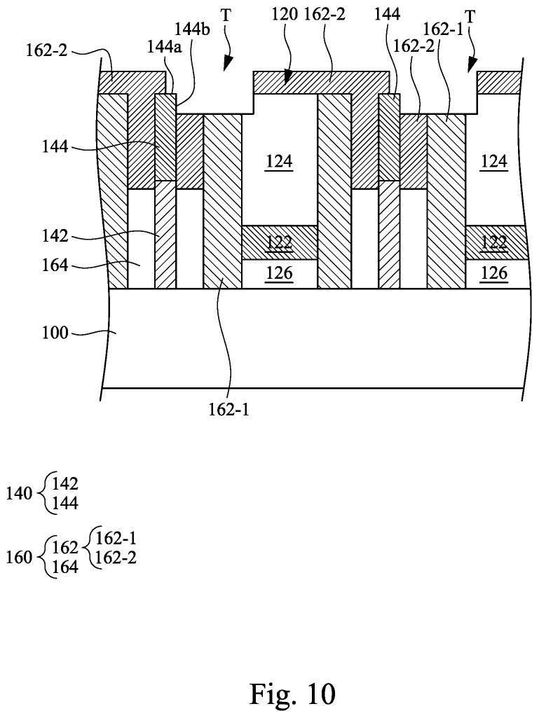

Reference is made to FIG. 10. The fabricating method includes etching the spacer material 162-1 and the spacer material 162-2 to expose the capacitor contact structure 140. To be more specific, after the etching process, a top surface and a sidewall of the capacitor contact structure 140 (e.g., the top surface 144a and the sidewall 144b of the upper contact plug 144) are exposed through the resultant trench T, as shown in FIG. 10. In some embodiments, as shown in FIG. 10, a portion of the cap layer of the bit line structure 120 is etched away after the etching process and the trench T exposes the cap layer 124.

Reference is made back to FIG. 3. The fabricating method includes forming a capacitor 180 electrically connected with the capacitor contact structure 140. To be more specific, the capacitor 180 is formed in the trench T. As shown in FIG. 3, the capacitor 180 is in contact with the exposed top surface and sidewall of the capacitor contact structure 140 (e.g., the top surface 144a and the sidewall 144b of the upper contact plug 144). In addition, the etched spacer material 162-2 is in contact with a sidewall of the capacitor 180. In embodiments where the cap layer 124 is exposed through the trench T, the capacitor 180 formed in the trench T is in contact with the bit line structure 120, or more particularly, with the cap layer 124.

As shown in FIG. 3, the capacitor 180 may include a bottom electrode, a dielectric layer, and a top electrode. During the fabrication of the capacitor 180, the bottom electrode and the dielectric layer may be conformally deposited in the trench T. As such, the bottom electrode and the dielectric layer of the capacitor 180 have a stepped profile to blanket-cover and contact the capacitor contact structure 140, as shown in FIG. 3.

Accordingly, in the memory device of some embodiments of the present disclosure, through the direct and multi-planar connection between the capacitor contact structure and the capacitor, the resistance of the capacitor contact structure may be reduced and the speed performance of the memory device may be improved. In addition, in the fabricating method of the memory device of some embodiments of the present disclosure, the process of forming a landing pad is omitted and the cost of the fabrication may be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A memory device, comprising:
a capacitor contact structure disposed on a semiconductor substrate;
a capacitor disposed on the capacitor contact structure, wherein the capacitor extends from a top surface of the capacitor contact structure to a sidewall of the capacitor contact structure;
a bit line structure disposed on the semiconductor substrate and adjacent to the capacitor contact structure; and
a spacer structure between the bit line structure and the capacitor contact structure.

2. The memory device of claim 1, wherein the spacer structure comprises a first spacer along a sidewall of the bit line structure and a second spacer along a sidewall of the capacitor contact structure.

3. The memory device of claim 2, wherein the first spacer and the second spacer are made of different materials.

4. The memory device of claim 2, wherein the first spacer further extends to the sidewall of the capacitor contact structure.

5. The memory device of claim 4, wherein the first spacer is in contact with a top surface of the second spacer.

6. The memory device of claim 5, wherein the capacitor contact structure comprises a lower contact plug and an upper contact plug over the lower contact plug, and wherein the top surface of the second spacer is lower than a top surface of the lower contact plug.

7. The memory device of claim 1, wherein the spacer structure extends to a top surface of the capacitor contact structure.

8. The memory device of claim 1, wherein a bottom surface of the capacitor is in contact with the spacer structure.

9. The memory device of claim 1, wherein the bit line structure further comprises a bit line and a cap layer over the bit line, and the capacitor is in contact with the cap layer.

10. The memory device of claim 9, wherein a bottom surface of the capacitor is lower than a top surface of the cap layer.

11. The memory device of claim 1, wherein the bit line structure further comprises a bit line and a cap layer over the bit line, and the spacer structure is in contact with a top surface of the cap layer.

12. A fabricating method of a memory device, comprising:
forming a bit line structure over a semiconductor substrate;
forming a first spacer along the bit line structure;
forming a second spacer along the first spacer;
forming a capacitor contact structure along the second spacer;
etching back the second spacer to form a gap between the first spacer and the capacitor contact structure;
forming a third spacer filling the gap and over the first spacer;
etching the first spacer and the third spacer to expose the capacitor contact structure; and
forming a capacitor electrically connected with the capacitor contact structure.

13. The fabricating method of claim 12, wherein etching the first spacer and the third spacer is performed to expose a top surface and a sidewall of the capacitor contact structure.

14. The fabricating method of claim 13, wherein the capacitor is in contact with the top surface and the sidewall of the capacitor contact structure.

15. The fabricating method of claim 12, wherein etching the first spacer and the third spacer is performed to expose a cap layer of the bit line structure, and the capacitor is in contact with the bit line structure.

16. The fabricating method of claim 12, wherein the capacitor contact structure comprises a lower contact plug and an upper contact plug over the lower contact plug, and wherein etching back the second spacer is performed such that a top surface of the etched second spacer is lower than a top surface of the lower contact plug.

17. The fabricating method of claim 12, wherein the first spacer and the third spacer comprise a same material.

18. The fabricating method of claim 12, wherein the third spacer further extends to a top surface of the bit line structure.

19. The fabricating method of claim 12, wherein the third spacer is in contact with a sidewall of the capacitor.

20. The fabricating method of claim 12, wherein the third spacer is in contact with a top surface of the second spacer.
